(19) United States
(12) Patent Application Publication
(10) Pub. No.: US 2011/0038129 A1
(43) Pub. Date: Feb. 17, 2011

(54) FLAT PANEL DISPLAY DEVICE

(75) Inventors: SHIH-LUNG HSU, Tu-Cheng (TW); CHUN-YU YU, Tu-Cheng (TW); KUANG-LUNG LIN, Tu-Cheng (TW); CHIEN-YUAN HUANG, Tu-Cheng (TW); MIN-HSIUNG HUNG, Tu-Cheng (TW); CHO-MING WU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/822,255

(22) Filed: Jun. 24, 2010

(30) Foreign Application Priority Data
Aug. 13, 2009 (CN) 200920307923.6

(51) Int. Cl. H05K 5/00

(52) U.S. Cl. 361/752

(57) ABSTRACT

A flat panel display device includes a housing, a display panel, a main frame, a power supply module, and a circuit board assembly. The housing is for receiving the display panel, the main frame, the power supply module, and the circuit board assembly. The main frame is fixed on the housing and is integrated with the housing. The display panel is secured on the main frame. The power supply module is secured on the main frame and is electrically connected to the display panel. The circuit board assembly is secured on the main frame and is electrically connected to the display panel and the power supply module.

### BACKGROUND

1. Technical Field

The present disclosure relates to display devices, and particularly to a flat panel display device.

2. Description of Related Art

A flat panel display device usually includes a housing, a display panel, a power supply module, a circuit board assembly, and a plurality of frames. The housing is used for receiving the display panel, the power supply module, the circuit board assembly, and the main frames. In order to firmly fix the power supply module and the circuit board assembly in the housing, the number of the main frames is often large. It is inconvenient to assemble and disassemble the flat panel display device.

Therefore, there is room for improvement in the art.

### BRIEF DESCRIPTION OF THE DRAWINGS

The components of the drawings are not necessarily drawn to scale, the emphasis instead being placed upon clearly illustrating the principles of the embodiment of a flat panel display device. Moreover, in the drawings, like reference numerals designate corresponding parts throughout several views.

FIG. 1 is an isometric, schematic view of a flat panel display device according to an exemplary embodiment.

FIG. 2 is a partially exploded view of the flat panel display device of FIG. 1.

FIG. 3 is a partially exploded, schematic view of the flat panel display device of FIG. 1.

### DETAILED DESCRIPTION

Embodiments of the present disclosure will now be described in detail with reference to the drawings.

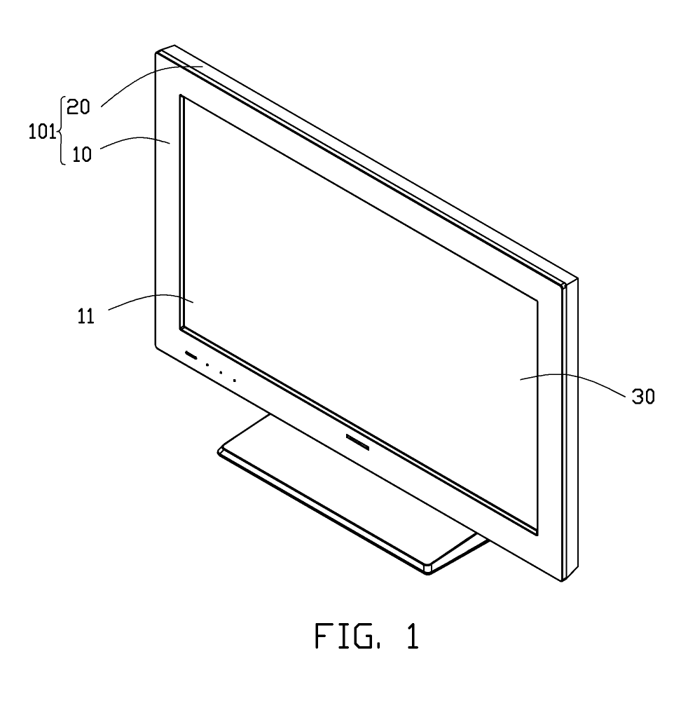

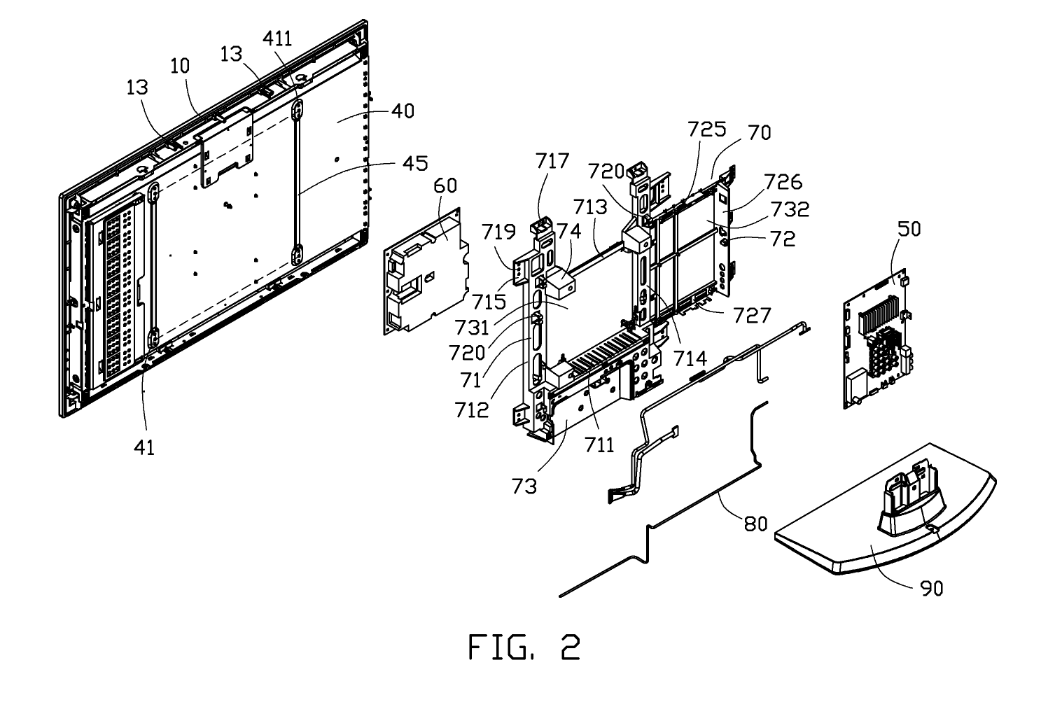

Referring to FIGS. 1 and 2, a flat panel display device 100 according to an exemplary embodiment is illustrated. The flat panel display device 100 includes a housing 101, a display panel 30, a circuit board assembly 50, a power supply module 60, a main frame 70, several electric wires 80, and a stand 90. The flat panel display device 100 may be a liquid crystal display device for a liquid crystal display TV or a liquid crystal display monitor, and the display panel 30 may be a standard liquid crystal display panel.

The housing 101 is used for receiving the display panel 30, the circuit board assembly 50, the power supply module 60, the main frame 70, and several electric wires 80. The housing 101 includes a front casing 10 and a rear casing 20. The front casing 10 clamps the rear casing 20 to define the housing 101. The front casing 10 defines an opening 11. The front casing 10 includes two first limiting portions 13. The first limiting portions 13 are set on the same side of the front casing 10 and face the rear casing 20.

The display panel 30 is located between the front casing 10 and the fixing member 40. The display panel 30 is used for displaying video signals for users and is exposed through the opening 11 of the front casing 10. A fixing member 40 is used for carrying the display panel 30. The fixing member 40 is located between the front casing 10 and the rear casing 20. The fixing member 40 includes four first fixing portions 41, and two strengthening ribs 45. The four first fixing portions 41 are set on four corners of a rectangle. Each first fixing portion 41 defines a plurality of limiting holes 411. One strengthening rib 45 connects two first fixing portions 41, and the other strengthening rib 45 connects the other two first fixing portions 41. The two strengthening ribs 45 are substantially parallel to each other.

The main frame 70 is made of plastic and is integrated into a single part through plastic injection molding process. The main frame 70 may be used for supporting the flat panel display device 100 and further for fixing all circuit boards, such as the circuit board assembly 50 and the power supply module 60. The main frame 70 includes a first frame 71, a second frame 72, and a supporting portion 73.

The first frame 71 includes a first flange 711, a second flange 712, a third flange 713, and a fourth flange 714. The four flanges 711, 712, 713, and 714 are perpendicularly interconnected to define a first receiving room 731 in the first frame 71.

The first flange 711 is set on the supporting portion 73. The first flange 711 is substantially parallel to the third flange 713, and is substantially perpendicular to the two strengthening ribs 45.

The second flange 712 is substantially parallel to the fourth flange 714 and the strengthening ribs 45. Each of the second flange 712 and the fourth flange 714 include two second fixing portions 715, a second limiting portion 717, and a clamping portion 720. Each of the second fixing portions 715 and the second limiting portions 717 define a plurality of through holes 719.

In this embodiment, a plurality of screws (not shown) is used to fasten the main frame 70 on the fixing member 40. The screws are engaged with the limiting holes 411 after extending through the through holes 719 of the second fixing portions 715, and the two first limiting portions 13 are engaged with the through holes 719 of the second limiting portions 717 to firmly fix the main frame 70 and the housing 101.

The clamping portion 720 is hook-shaped, and is used for clamping the electric wires 80. The electric wires 80 are used for electrically connecting the display panel 30, the power supply module 60, and the circuit board assembly 50.

The second frame 72 is similar to the first frame 71. The second frame 72 includes the fourth flange 714 shared with the first frame 71, a fifth flange 725, a sixth flange 726, and a seventh flange 727. The four flanges 714, 725, 726, and 727 are perpendicularly interconnected to define a second receiving room 732 in the second frame 72.

The fifth flange 725 extends from the third flange 713, and is substantially perpendicular to the fourth flange 714. The seventh flange 727 extends from the first flange 711, and is substantially perpendicular to the fourth flange 714. The sixth flange 726 connects the fifth flange 725 to the seventh flange 727, and is substantially parallel to the fourth flange 714.

Three installing members 74 are fixed on the main frame 70. The installing members 74 are configured for fixing to a wall mount bracket (not shown). Thus, the flat panel display device 100 can be hung up on a wall by the wall mount bracket.

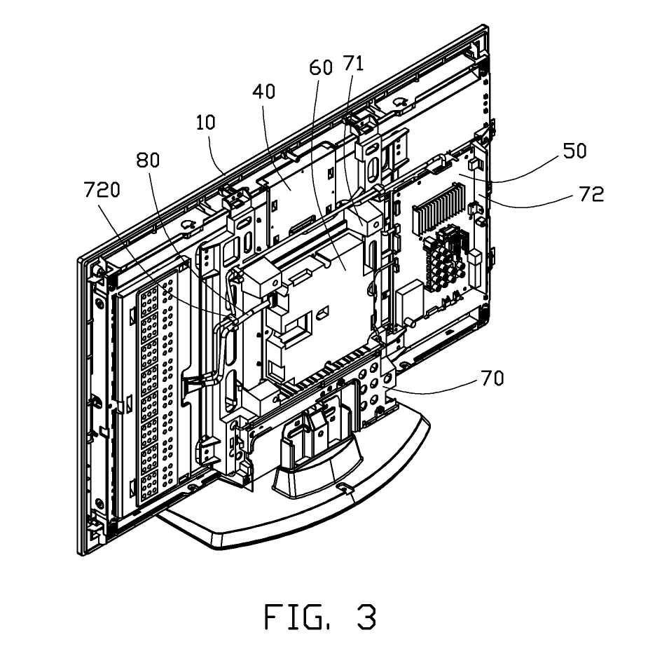

Further referring to FIG. 3, the supporting portion 73 is set under the first flange 711, and is used for being engaged with the stand 90. The supporting portion 73 is used for supporting the flat panel display device 100.

The power supply module 60 is electrically connected to the display panel 30 and the circuit board assembly 50 for powering thereof. The power supply module 60 is fastened in the first frame 71 by the four flanges 711, 712, 713, and 714, and is located between the two casings 10 and 20. The circuit board assembly 50 is fastened in the second frame 72 by the four flanges 714, 725, 726, and 727, and is located between the two casings 10 and 20.

As described above, the main frame 70 is integrated, and the circuit board assembly 50 and the power supply module 60 are embedded in the main frame 70, thus, it is easy and convenient to assemble or disassemble the circuit board assembly 50 and the power supply module 60 in or from the flat panel display device 100.

While various exemplary and preferred embodiments have been described, it is to be understood that the disclosure is not limited thereto. To the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A flat panel display device, comprising:
a housing;
a main frame received in the housing, the main frame fixed on and integrated with the housing;
a display panel received in the housing and secured on the main frame;
a power supply module secured on the main frame and electrically connected to the display panel; and
a circuit board assembly secured on the main frame and electrically connected to the display panel and the power supply module.

2. The flat panel display device of claim 1, further comprising a fixing member for carrying the display panel, the fixing member is fixed on the main frame.

3. The flat panel display device of claim 2, wherein the main frame comprises:
a first frame for receiving the power supply module and fastening the power supply module in the housing; and
a second frame for receiving the circuit board assembly and fastening the circuit board assembly in the housing.

4. The flat panel display device of claim 1, wherein the main frame comprises a clamping portion, the clamping portion is adapted to clamp electric wires electrically connecting the display panel, the power supply module, and the circuit board assembly.

5. The flat panel display device of claim 4, wherein the clamping portion is hook-shaped.

6. The flat panel display device of claim 3, wherein the first frame is parallel to the second frame, and shares the same flange with the second frame.

7. The flat panel display device of claim 3, wherein the fixing member defines a plurality of limiting holes, the main frame defines a plurality of through holes, the flat panel display device further comprises a plurality of screws for fastening the main frame on the fixing member, the screws are engaged with the limiting holes of the fixing member after extending through the through holes of the main frame.

8. The flat panel display device of claim 7, wherein the fixing member comprises a plurality of fixing portions, the plurality of limiting holes is defined on the plurality of fixing portions.

9. The flat panel display device of claim 8, wherein the fixing member further comprises a plurality of strengthening ribs, each strengthening rib is for connecting two of the plurality of fixing portions.

10. The flat panel display device of claim 3, wherein the housing comprises a plurality of first limiting portions, the main frame defines a plurality of through holes, the flat panel display device further comprises a plurality of screws for fastening the housing and the main frame, the screws are engaged with the plurality of first limiting portions after extending through the through holes of the main frame.

11. The flat panel display device of claim 10, wherein the fixing member comprises a plurality of second fixing portions, the plurality of through holes is defined on the plurality of second fixing portions.

12. The flat panel display device of claim 1, wherein the housing comprises a front casing and a rear casing clamping with the front casing, the front casing defines an opening, the display panel displays video signals and is exposed through the opening of the front casing.

13. The flat panel display device of claim 3, wherein the main frame further comprises a supporting portion for supporting the flat panel display device, the supporting portion is set under one of the first frame and the second frame, and is used for being engaged with a stand of the flat panel display device.

14. The flat panel display device of claim 1, wherein the main frame comprises a plurality of installing members ready for fixing with a wall mount bracket of the flat panel display device as to be hung up on a wall by the wall mount bracket.

15. The flat panel display device of claim 1, wherein the main frame is made of plastic and is integrated into a single part through plastic injection molding process.

16. A flat panel display device, comprising:
a display panel;
a main frame secured upon a rear of the flat display panel for supporting the flat display panel; and
at least one circuit board assembly for the flat display panel mounted on the main frame;
wherein the main frame is made of plastic and is integrated into a single part through plastic injection molding process.

17. The flat panel display device of claim 16, further comprising a front casing and a rear casing engaged to the front casing so as to define a housing for receiving the flat display panel, the main frame, and the at least one circuit board assembly.

18. The flat panel display device of claim 17, wherein the at least one circuit board assembly comprises a main circuit board assembly and a power board.

19. The flat panel display device of claim 16, wherein the main frame comprises a pair of vertical frames spaced apart, and each vertical frame is provided with two spaced fixing portions for engaging the flat display panel.

20. The flat panel display device of claim 19, wherein the main frame further comprises a supporting portion for supporting the flat panel display device, the supporting portion is set under one of the vertical frames, and is used for being engaged with a stand of the flat panel display device.
